(19) United States
(12) Patent Application Publication
(10) Pub. No.: US 2015/0073748 A1
(43) Pub. Date: Mar. 12, 2015

(54) METHOD AND SYSTEM FOR MEASURING TRAFFIC FLOW IN A BUILDING

(71) Applicants: Veikko MATTSSON, Hyvinkaa (FI); Risto KONTTURI, Rajamaki (FI)

(72) Inventors: Veikko MATTSSON, Hyvinkaa (FI); Risto KONTTURI, Rajamaki (FI)

(73) Assignee: KONE CORPORATION, Helsinki (FI)

(21) Appl. No.: 14/543,343

(22) Filed: Nov. 17, 2014

Related U.S. Application Data
(63) Continuation of application No. PCT/EP2012/062490, filed on Jun. 27, 2012.

(51) Int. Cl. G06Q 10/06; G01R 33/06; G01P 15/00; G01B 11/00

(52) U.S. Cl. CPC G06Q 10/063; G01B 11/00; G01R 33/06; G01P 15/00
USPC 702/150

(57) ABSTRACT

The invention relates to a method for measuring the traffic flow in a building having a people mover system, in which method the following succession of steps is performed:
at least two monitoring units with at least one sensor are temporarily installed in the vicinity of entrance- and/or exit area(s) of at least one people mover,
each of the monitoring units is provided with a power supply for being operated as an independent unit,
events caught by the sensor are associated with the current event time and with the location/position of the corresponding monitoring unit as correlated event/event time/event location data, which correlated event/event time/event location data is used to compute a traffic flow in the building. This data can be advantageously used in the call allocation of a new people mover system of said building.

This application is a continuation of PCT International Application No. PCT/EP2012/062490 which has an International filing date of Jun. 27, 2012, the entire contents of which are incorporated herein by reference.

The present invention refers to the determination of traffic flow in the people mover system of a building. Such a people mover system may comprise escalators and/or elevators which are intended to convey passengers and/or goods to their destination in an area, particularly in a building.

Such data is important for the optimization of the people mover system, particularly in course of the renovation or replacement of an existing people mover system. The retrieved data about traffic flow can be for example input to a call allocation system of the people mover control so as to optimize per se well known targets in call allocation, e. g. minimization of travelling time or waiting time or optimization of the energy use or maximization of the traffic flow in total.

Accordingly, the object of the present invention is to create a method and system for retrieving traffic flow data in a building with minor effort. According to the invention this object is solved with the features of claims 1 and 11. Preferred embodiments of the invention are subject matter of the corresponding dependent claims.

For retrieving traffic flow data monitoring units are temporarily located in the area. Generally, the term “area” stands for any area which may comprise one or several buildings as e.g. a fair location or an airport. Anyway, the term area also may indicate one single building of a part thereof. Hereinafter the term “building” is used as a specific example of an area whereby it shall be understood that the invention may always be applied to larger or smaller areas as well.

First, it has to be mentioned that monitoring units are installed temporarily in the building, which means that they are installed only for a time period (monitoring period) which is necessary to retrieve the necessary event data to establish traffic flow information of an area. This may be a few days, one or several weeks or—e.g. in case of large areas with changing traffic as e.g. fairs—one or several months.

The temporary installation also means that the monitoring units are mounted at the entrance/exit areas of a people mover system such that they can easily be removed. They can for example be mounted to the entrance exit areas with bolts, with magnet tapes or adhesive tapes. In an elevator system e.g. each monitoring unit is mounted detachably at a car wall or ceiling. The monitoring unit can be mounted with a magnetic plate or with an adhesive tape or with small bolts which do not hamper the appearance of the mounting base after the monitoring unit is detached. By these measures it is ensured that the appearance of the people mover system is not impaired when the monitoring units are removed after the monitoring period.

Preferably, a monitoring unit is placed in locations of the building which are adapted to contribute relevant information for the general traffic flow data. Generally, it is assumed that reliable information about traffic flow is obtained when at each entrance and/or exit area of the people mover system a monitoring unit is located, whereby an entrance area can be also an exit area (e.g. an elevator car door area). By this means it is possible to monitor the complete traffic in the people mover system of the area. In an elevator system these areas are preferably the landing doors of each floor and of each elevator. Additionally the entrance lobby of the building may be monitored, if desired.

The monitoring units may use currently known types of sensors for monitoring an area on the movement or existence of persons or goods, as e.g. cameras, IR-sensors, optical sensors.

The monitoring unit comprises at least one sensor which is able to determine whether or not a passenger has entered an elevator car or an escalator entrance/exit area or whether or not a car door has opened etc. Preferably, this event data is taken or processed into a textual event. With the term “textual event” a data format is meant which does not comprise graphical data but only data about whether or not an event has happened and possibly what kind of event has happened (entrance or exit of a passenger, number of passengers). This is important as graphical data comprises large data volumes which are to be handled and transmitted. The transmission of large data volumes is troublesome so that preferably the event data is processed into textual data already in the monitoring unit, before any transmission of said data may occur. Even if cameras are used as sensors the graphic information obtained by the cameras is preferably immediately processed into textual data. On this behalf the monitoring unit preferably comprises a microprocessor for the immediate processing of the graphic signals of the camera into textual data.

The event data may comprise all data relating to any traceable changes in the car interior as passenger entering/leaving the car, door-to-open time, door-to-close time etc. All these parameters can be handled as a corresponding event, e.g. “passenger-entering event”, “passenger-leaving event”, “car-empty event”, “car-full event”, “door-open event”, “door-close event”. Accordingly, the event-data may comprise different parameters—preferably in addition to the time and location of the occurrence of the corresponding event.

With camera based-sensors it is further possible to track each passenger when he/she enters and when he/she exits the area monitored by the camera-based sensor, as based on camera data an adapted tracking software is able to detect and trace a passenger as one separate entity apart from others. Hereby it is possible to identify for example the departure floor and destination floor of each passenger. If data of several camera-based sensors are combined (in the recording/processing unit), it is for example possible to identity the whole track of each passenger from the entrance door to the destination floor. This enables the elevator builder to exactly adapt the new people mover system to the detailed needs of the persons in the building.

The information taken by the sensors of the monitoring units can be processed in different ways. One alternative is to provide the monitoring units with a wireless communication link which communication link is able to communicate with a corresponding communication link of a reporting unit. The reporting unit is able to record and process all the events communicated from the different monitoring units. In this connection the recording unit and/or the monitoring units preferably have a clock so that the events communicated by the different monitoring units can be correlated to the event time.

Preferably each monitoring unit transmits an individual ID to the recording unit—or transmits on a different carrier frequency—which enables the recording unit to correlate the transmitted event data and the event time data to the event location data—the location of the transmitting monitoring unit—which provides a sufficient data set for establishing the traffic flow information for the monitored area via the events caught with the sensors of the monitoring units. The ID can be added to the event data or may be transmitted as separate data in conjunction with the event data.

In this connection it is only relevant that the recording unit gathers the event data and all correlated data as event time and event location whereas the processing of the traffic flow from these data can be performed in the recording unit or later on in a separate processing unit.

The computed traffic flow can be used later for the control of the people mover system in said area, either during the optimization of an existing control or during a renovation of the people mover system with a modern control system.

In case at least one of said monitoring units is located in an elevator car preferably an acceleration sensor or magnetometer is used in said monitoring unit to obtain event location data of the elevator car. In this case it is possible that the monitoring unit does not only provide data about the elevator car in which the monitoring unit is located but also at which stop floor the events happening in entrance/exit area of the elevator car take place. By this means it is not necessary to provide monitoring units at each landing door of each floor of a building.

If the monitoring units comprise its own clock for the establishment of the event time data preferably the clocks of all monitoring units are synchronized at the beginning of the monitoring phase. By this measure it can ensured that the event time data taken by the different monitoring units are in synchronization.

In very crowded lobbies for example in base floors or ground floors it can be necessary to provide for the monitoring period a fence arrangement which guides the passengers to the entrance/exit area one by one which better enables the monitoring units to catch each passenger separately. This measure therefore increases the reliability and the accuracy of the events caught by the sensors.

In a preferred embodiment of the invention it is possible to work without any communication links in the monitoring units if the monitoring units comprise a memory which is detachable. Such a memory can preferably be an SD-card or a USB-stick. In this case preferably the monitoring unit comprises a clock and when the event data and the event time data provided by the clock is stored in a memory also the ID of the monitoring unit is stored together with the event data on the memory card so that it is possible to track the location of the monitoring unit when the data is processed later on, e. g. after the monitoring period. This arrangement is very economic as no efforts for data transmission have to be taken during the monitoring period. Also in this case the monitoring unit may comprise an acceleration sensor or a magnetometer. Then position data from the acceleration sensor or magnetometer can be stored on the detachable memory so that the complete data set with event data, event time and event location is available for processing.

A magnetometer is a preferable means to obtain information about the floor of the elevator on which the event data has been established. Thus, at the beginning of the monitoring period at least one test run is made with the elevator car driving from the uppermost to the lowermost floor. Hereby the magnetometer takes up an individual magnetic reference profile of the over the complete shaft height. During the monitoring period the actual car position can always be exactly derived by comparing the current magnetometer data with the magnetic reference profile.

It is also possible to provide each monitoring unit with a memory as well as with a communication link. In this case the memory must not be detachable because in this case the stored data can be read out during the monitoring period or afterwards with a reading device communicating with the communication link of the monitoring unit which reading devices can be connected to the recording units to further process the event, event time and event location data. The communication link can be wireless or wire-based.

The power supply of the monitoring unit is preferably a battery or an accumulator which keeps the monitoring unit independent of the power supply of the people mover system.

Preferably the computed traffic flow data is later on used in a call allocation algorithm of the control of the people mover system, e. g. in an elevator group control.

The above mentioned embodiments may be combined with each other arbitrarily as long as there are no technical contradictions occurring in such combination.

The invention will be described hereinafter with the aid of the schematic drawing. In this drawing:

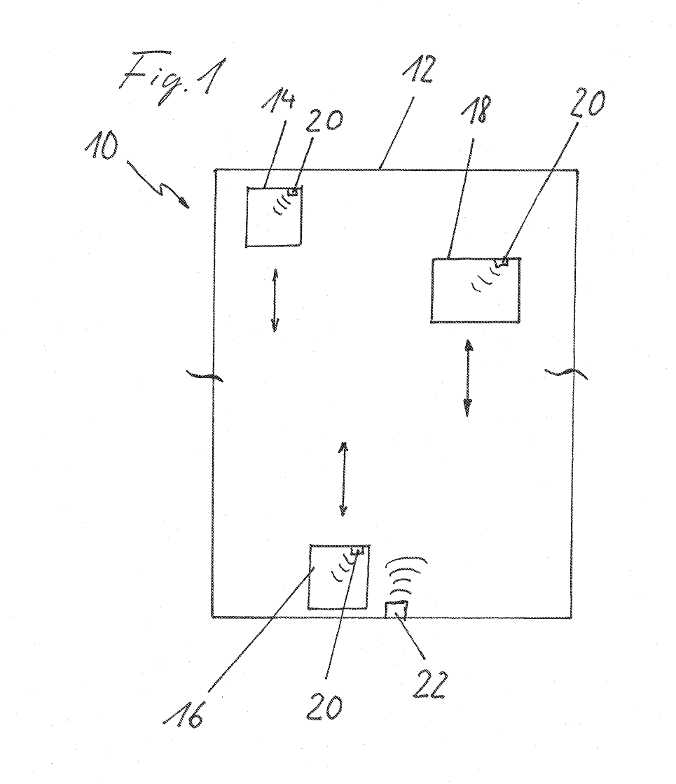

FIG. 1 shows schematic illustration diagram of an elevator group with three elevators,

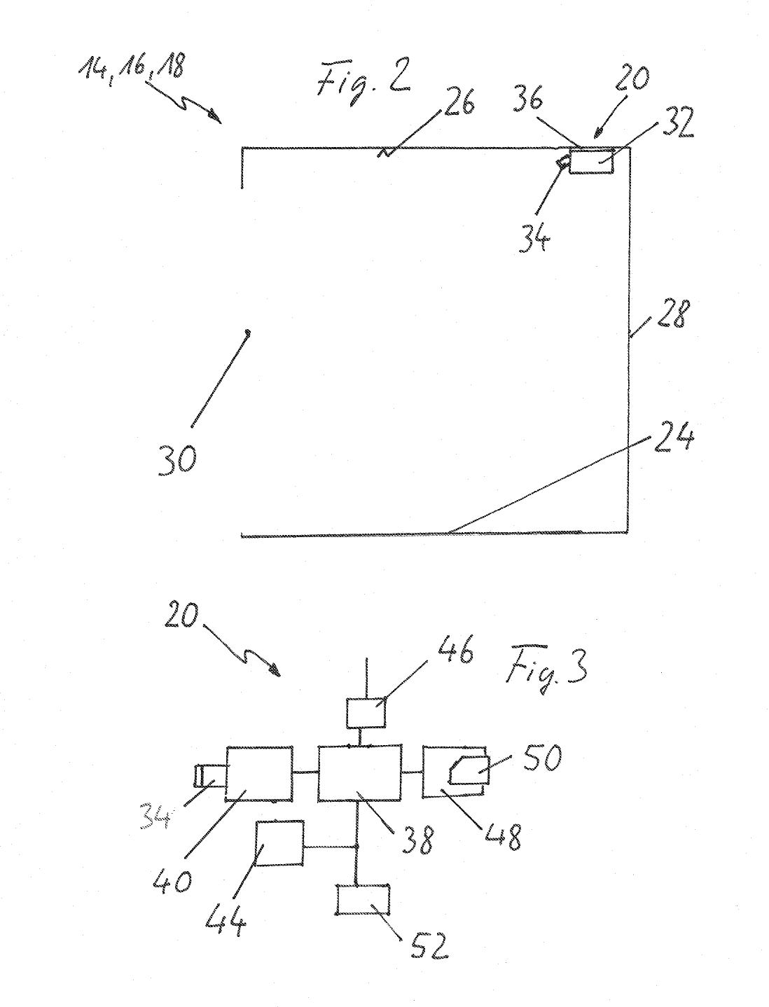

FIG. 2 shows a diagram of an elevator car comprising a monitoring unit, and

FIG. 3 shows a diagram of the components located in a monitoring unit.

FIG. 1 shows an elevator group 10 having an elevator shaft 12 in which two passenger elevator cars 14, 16 are moving vertically. These passenger cars are configured for passenger transport. Further one load elevator 18 is located in the elevator shaft 12, which load elevator 18 is configured to transport large groups of passenger or bulky and/or heavy loads. In each of these elevator cars 14, 16, 18 a monitoring unit 20 is provided having a sensor which scans the car door area. Each monitoring unit 20 communicates wirelessly with a recording unit 22 located at an adapted space in the elevator shaft 12, preferably on its bottom.

The monitoring unit 20 comprises a sensor for scanning the door area, a wireless communication link for the communication with the recording unit 22 as well as an acceleration sensor or magnetometer for obtaining information about the vertical position (floor) of the respective elevator car 14, 16, 18 in the elevator shaft 12.

Furthermore, each monitoring unit 20 of the cars 14, 16, 18 preferably transmits a unique ID to the recording unit 22 which is then able to differentiate the incoming signals from the three different monitoring units 20 of the elevator cars 14, 16, 18.

With that information the recording unit 22 obtains event data from the sensors of the monitoring units 20 as well as event location data via the ID of the monitoring unit as well as the position data retrieved from the acceleration sensor or magnetometer.

The monitoring units 20 and/or the recording unit 22 comprises a clock so that each event caught by the sensor of the monitoring units 20 is immediately correlated to the current event time which allows the recording unit to specify the events in time as well as location.

FIG. 2 shows an elevator car 14, 16, 18 of FIG. 1 in more detail. The elevator car has a car bottom 24 and a car ceiling 26 as well as side walls 28. In one of the side walls 28 a car door area 30 is provided which is monitored by the monitoring unit 20. The monitoring unit 20 comprises a casing 32 from which an objective lens 34 of a camera of the monitoring unit 20 protrudes in the direction of the car door 30. The casing 32 has a magnetic bottom plate 36 so that the monitoring unit 20 can be fastened without any effort to the metal ceiling 26 of the elevator car.

A more detailed diagram of the monitoring unit 20 is shown in FIG. 3. Accordingly, the monitoring unit 20 comprises a control unit 38 to which a camera 40 with an objective lens 34 is coupled. Furthermore, the monitoring unit 20 comprises its own power supply, preferably an accumulator 44. Furthermore, the control unit 38 is connected with a wireless communication link 46 for the communication with a recording unit 22 or with a hand-held device for reading out event data stored in a memory unit 48 to which the control unit 38 of the monitoring unit 20 is connected. The memory unit 48 preferably comprises changeable memory devices, such as SD-cards 50 or other types of flash memories. Finally the control unit 38 of the monitoring unit 20 is connected with an acceleration sensor 52, e. g. a magnetometer to track the position of the elevator car in the elevator shaft.

Such kind of monitoring unit 20 is able to store each event data obtained by the camera 40 correlated with the event time obtained by an internal clock of the control unit 38 and with the event location data obtained by an internal ID which is e.g. written into a ROM of the control unit 38 and via the data from the acceleration sensor or magnetometer 52.

In this arrangement the monitoring unit 20 the control unit 38 comprises a microprocessor and is thus able to process the graphic event data of the camera into textual data and to store the correlated event, event time and event location data on the SD-card 50. Alternatively, the control unit 38 is able to communicate via the communication link 46 with the recording unit 22 to send each event data together with any kind of event location data, as e. g. the monitoring unit ID and information from the acceleration sensor or magnetometer 52. In this case no memory would be necessary in addition to the RAM of the control unit 38.

The monitoring unit 20 of FIG. 3 is on the other side able to track and catch all events in said elevator car without any interaction with external devices, e. g. without any interaction with the recording unit 22.

After the end of the monitoring period the SD-card 50 of all monitoring units can be collected and written out by a recording or processing unit. In this recording or processing unit all the necessary calculations can be made for retrieving traffic flow information from the event data, event time data and event location data of all monitoring units 20. This recording or processing unit can be e.g. located at the elevator company.

In case the monitoring unit 20 is only intended for direct interaction with the recording unit 22 it does not need an internal memory 48, 50. On the other hand, if all the event data is to be stored on the memory 48 in connection with the SD-card 50 and to be processed after the monitoring period no communication link 46 is required. The provision of both features enable the operation of the monitoring unit 20 according to the preferred of the above mentioned operation alternatives.

The sensor does not need to be a camera 40 with an objective 42 but may also be an infrared sensor or other per se known monitoring sensor for people detection.

The memory 48 can also be flash memory or a memory working in connection with USB-sticks and other changeable media which are per se known.

The invention is not limited to the embodiment but can be varied within the scope of the enclosed claims.

1. Method for measuring the traffic flow in a building having a people mover system, in which method the following succession of steps is performed:
at least two monitoring units with at least one sensor are temporarily installed in the vicinity of entrance- and/or exit area(s) of at least one people mover,
each monitoring unit is provided with a power supply for being operated as an independent unit,
events caught by the sensor are associated with the current event time and with the location/position of the corresponding monitoring unit as correlated event/event time/event location data, which correlated event/event time/event location data is used to compute a traffic flow in the building.

2. Method according to claim 1, wherein the data transfer of each of the monitoring units is performed via a detachable memory.

3. Method according to claim 1, wherein the data transfer of each of the monitoring units is performed via a wireless communication link.

4. Method according to claim 1, wherein events detected by the sensor are stored in a memory of the respective monitoring unit in connection with the current event time as correlated event/event time data.

5. Method according to claim 1, wherein events caught by the sensor are transferred wirelessly to a recording unit having a memory for storing all kinds of event data.

6. Method according to claim 1, wherein the event data and/or correlated event/event time data and/or correlated event/event time/event location data is processed in the recording unit for computing the traffic flow in the building from the event data.

7. Method according to claim 1, wherein the event data is transferred from graphic data into textual data for the further processing.

8. Method according to claim 1, wherein the computed traffic flow is fed to a call allocation unit of the control of a new/renovated people mover system after replacement/renovation of the current people mover system.

9. Method according to claim 1, wherein at least one of said monitoring units is located in an elevator car and an acceleration sensor or magnetometer is used in said monitoring unit to obtain event location data of the elevator car, which location data is added to the correlated event/event time data to obtain correlated event/event time/event location data.

10. Method according to claim 1, wherein all entrance and exit areas of the people mover system are provided with a monitoring unit.

11. Arrangement for the monitoring of the traffic flow in a people mover system in an area comprising elevators and/or escalators in line with a method of claim 1, which arrangement has following elements:
at least two monitoring units temporarily located in an entrance/exit area of at least one people mover in the people mover system of the area which monitoring units comprise at least one sensor for detecting event data and a power supply, respectively.

12. Arrangement according to claim 11, wherein at least one of said monitoring units comprises a wireless communication link and the arrangement further comprises a reporting unit having a wireless communication link for data transfer with the wireless communication link of the monitoring units.

13. Arrangement according to claim 11, wherein at least one of said monitoring units comprises acceleration sensor.

14. Arrangement according to claim 11, wherein at least one of said monitoring units comprises a memory for storing event data.

15. Arrangement according to claim 14, wherein the memory is detachable.

16. Arrangement according to claim 11, wherein a fence is provided in the lobby of the floor with the highest traffic to allow the entrance of passengers to the entrance area of the people mover system only one after the other.

17. Arrangement according to claim 11, wherein the recording unit is provided in the elevator shaft and comprises a memory for storing event data with a correlated event time and event location.
